(19) United States
(12) Patent Application Publication
(10) Pub. No.: US 2024/0234096 A1
(43) Pub. Date: Jul. 11, 2024

(54) PLASMA PROCESSING APPARATUS AND METHOD FOR FABRICATING SEMICONDUCTOR DEVICE USING THE SAME

(71) Applicant: SAMSUNG ELECTRONICS CO., LTD., Suwon-si (KR)

(72) Inventors: Nam Jin CHO, Suwon-si (KR); Yi Hwan KIM, Suwon-si (KR); Sang Chul HAN, Suwon-si (KR); Sang Ki NAM, Suwon-si (KR); Jun Ho LEE, Suwon-si (KR); Hyun Jae LEE, Suwon-si (KR)

(21) Appl. No.: 18/239,155

(22) Filed: Aug. 29, 2023

(30) Foreign Application Priority Data
Jan. 9, 2023 (KR) 10-2023-0002787

(51) Int. Cl. H01J 37/32; C23C 16/26; C23C 16/48

(52) U.S. Cl. CPC H01J 37/3244; C23C 16/26; C23C 16/48; H01J 37/3211; H01J 37/32623; H01J 2237/3321; H01L 21/033

(57) ABSTRACT

A method for fabricating a semiconductor device includes loading a substrate into a lower region in a chamber separated by a shower head into the lower region and an upper region, supplying a source gas to the upper region, generating plasma including ions and radicals in the upper region, using a magnetic field and an electric field generated from an antenna on the upper region, and the source gas, supplying the ions and the radicals generated in the upper region into the lower region through a plurality of plasma inlet holes formed to penetrate the shower head in a vertical direction, supplying a process gas into the lower region through a plurality of process gas supply holes formed in the shower head, and forming a deposition film on the substrate inside the lower region, using the ions, the radicals and the process gas.

### CROSS-REFERENCE TO RELATED APPLICATION

This application claims priority from Korean Patent Application No. 10-2023-0002787 filed on Jan. 9, 2023, in the Korean Intellectual Property Office and all the benefits accruing therefrom under 35 U.S.C. 119, the contents of which in its entirety are herein incorporated by reference.

### BACKGROUND

### 1. Field

The present disclosure relates to a plasma processing apparatus and a method for fabricating a semiconductor device using the plasma processing apparatus.

### 2. Description of the Related Art

An amorphous carbon layer (ACL) process, which is one of chemical vapor deposition (CVD) processes of a semiconductor, may be used to form a hard mask. A hard mask with a high selectivity may address a high aspect ratio, and an increased ACL process temperature may increase the quality of a resultant hard mask film. However, since an improvement in quality of the hard mask film with an increase in ACL process temperature has reached its limit, a diamond like carbon (DLC) film has been developed.

### SUMMARY

According to some embodiments of the present disclosure, there is provided a method for fabricating a semiconductor device, including loading a substrate into a lower region in a chamber separated by a shower head into the lower region and an upper region formed on the lower region, supplying a source gas to the upper region, generating a plasma including ions and radicals in the upper region, using a magnetic field and an electric field generated from an antenna disposed on the upper region, and the source gas, causing each of the ions and the radicals generated in the upper region to flow into the lower region through a plurality of plasma inlet holes formed to penetrate the shower head in a vertical direction, causing a process gas to flow into the lower region through a plurality of process gas supply holes formed in the shower head, and forming a deposition film on the substrate inside the lower region, using the ions, the radicals and the process gas.

According to some embodiments of the present disclosure, there is provided a plasma processing apparatus, including a chamber including a lower region and an upper region formed on the lower region, the upper region being a region in which a plasma including ions and radicals is generated, and the lower region being a region in which a vapor deposition process is performed on a substrate, a lower electrode disposed inside the lower region and onto which the substrate is loaded, a shower head separating the lower region and the upper region inside the chamber, a plurality of plasma inlet holes penetrating the shower head in a vertical direction, the plurality of plasma inlet holes causing each of the ions and radicals generated in the upper region to flow into the lower region, a plurality of process gas supply holes disposed in the shower head to supply a process gas to the lower region, a process gas supply unit supplying the process gas to the plurality of process gas supply holes, and an antenna disposed on the upper region to generate a magnetic field and an electric field inside the upper region.

According to some embodiments of the present disclosure, there is provided a plasma processing apparatus, including a chamber including a lower region and an upper region formed on the lower region, the upper region being a region in which a plasma including ions and radicals is generated, and the lower region being a region in which a vapor deposition process is performed on a substrate, a shower head separating the lower region and the upper region inside the chamber, a plurality of plasma inlet holes penetrating the shower head in a vertical direction, the plurality of plasma inlet holes causing each of the ions and radicals generated in the upper region to flow into the lower region, a plurality of process gas supply holes disposed in the shower head to supply a process gas to the lower region, a process gas supply unit supplying the process gas to the plurality of process gas supply holes, and an antenna disposed on the upper region to generate a magnetic field and an electric field inside the upper region, wherein a diameter of the plasma inlet hole is greater than a diameter of the process gas supply hole, and wherein the plasma is not generated inside the lower region, except the ions and the radicals flowing into the lower region through the plurality of plasma inlet holes.

According to some embodiments of the present disclosure, there is provided a plasma processing apparatus, including a chamber including a lower region and an upper region above the lower region, the upper region being a region in which a plasma including ions and radicals is generated, and the lower region being a region in which a vapor deposition process is performed on a substrate, a lower electrode inside the lower region of the chamber, the substrate being loaded onto the lower electrode, a shower head inside the chamber, the shower head separating the lower region and the upper region, plasma inlet holes penetrating the shower head in a vertical direction, the plasma inlet holes being configured to allow the ions and the radicals flow from the upper region to the lower region of the chamber, process gas supply holes in the shower head, the process gas supply holes being configured to supply a process gas to the lower region of the chamber, and a process gas supply configured to supply the process gas to the process gas supply holes, wherein each of the process gas supply holes is between two of the plasma inlet holes.

### BRIEF DESCRIPTION OF THE DRAWINGS

Features will become apparent to those of skill in the art by describing in detail exemplary embodiments with reference to the attached drawings, in which:

FIG. 1 is a schematic cross-sectional view of a plasma processing apparatus according to some embodiments of the present disclosure;

FIG. 2 is a plan view of a shower head shown in FIG. 1;

FIG. 3 is a plan view of a source gas supply unit shown in FIG. 1;

FIG. 4 is a flow chart of a method for fabricating a semiconductor device using the plasma processing apparatus according to some embodiments of the present disclosure;

FIGS. 5 to 8 are stages in a method for fabricating a semiconductor device using the plasma processing apparatus according to some embodiments of the present disclosure;

FIG. 9 is a diagram of a plasma processing apparatus according to some other embodiments of the present disclosure;

FIG. 10 is a diagram of a plasma processing apparatus according to some other embodiments of the present disclosure;

FIG. 11 is a plan view of a plasma adjusting unit shown in FIG. 10;

FIG. 12 is a flow chart of a method for fabricating a semiconductor device using the plasma processing apparatus according to some other embodiments of the present disclosure;

FIG. 13 is a stage in a method for fabricating a semiconductor device using the plasma processing apparatus according to some other embodiments of the present disclosure;

FIG. 14 is a plan view of a shower head of a plasma processing apparatus according to some other embodiments of the present disclosure;

FIG. 15 is a plan view of a shower head of a plasma processing apparatus according to some other embodiments of the present disclosure; and

FIG. 16 is a plan view of a shower head of a plasma processing apparatus according to some other embodiments of the present disclosure.

### DETAILED DESCRIPTION

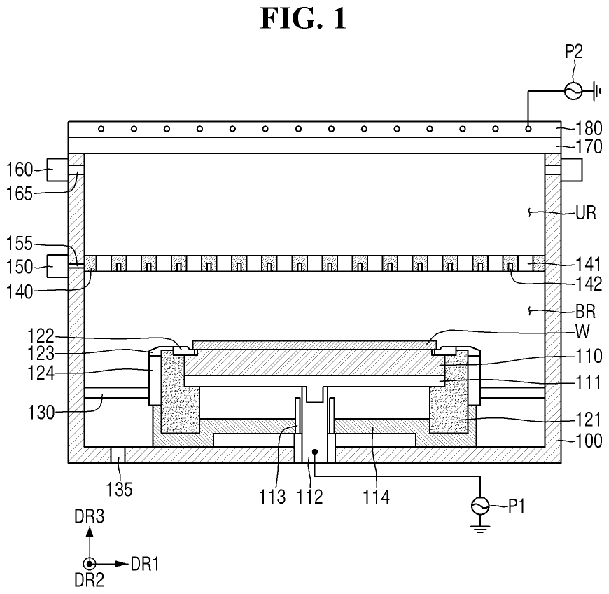

Hereinafter, a plasma processing apparatus according to some embodiments of the present disclosure will be described with reference to FIGS. 1 to 3.

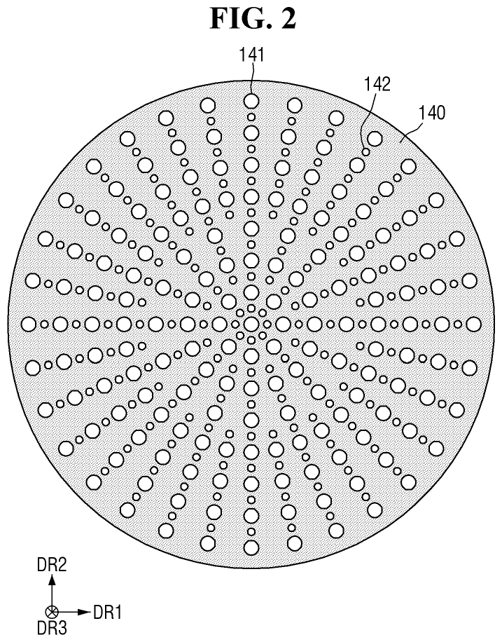

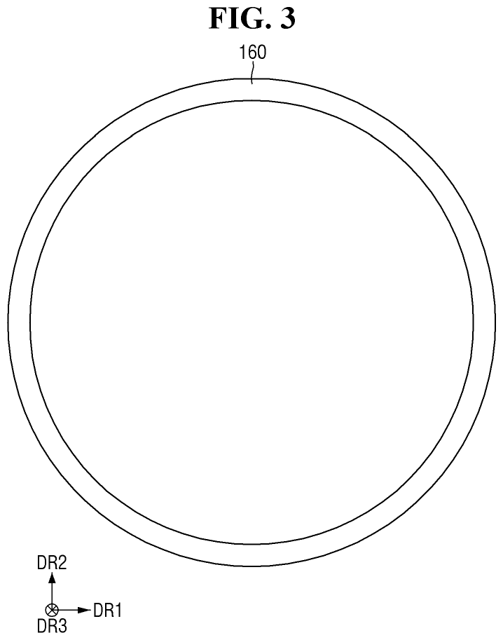

FIG. 1 is a diagram of a plasma processing apparatus according to some embodiments of the present disclosure. FIG. 2 is a plan view of a shower head shown in FIG. 1. FIG. 3 is a plan view of a source gas supply unit shown in FIG. 1.

Referring to FIGS. 1 to 3, the plasma processing apparatus according to some embodiments of the present disclosure includes a chamber 100, a lower electrode 110, an RF plate 111, an RF rod 112, a ground electrode 113, a ground plate 114, an insulating plate 121, a focus ring 122, an edge ring 123, an insulator ring 124, a baffle unit 130, a gas outlet 135, a shower head 140, a plurality of plasma inlet holes 141, a plurality of process gas supply holes 142, a process gas supply unit 150, a process gas supply line 155, a source gas supply unit 160, a source gas supply line 165, a window 170, an antenna 180, a first power source P1, and a second power source P2.

The chamber 100 may perform the function of a housing including other components inside. The chamber 100 may include an interior space (e.g., an isolated space) in which a substrate W is subjected to a plasma process. As the interior of the chamber 100 is isolated from the outside, the process conditions of the plasma process may be adjusted. For example, processing conditions, e.g., temperature and pressure, inside the chamber 100 may be adjusted, e.g., to be different from those outside.

The chamber 100 may include a lower region BR and an upper region UR on, e.g., above, the lower region BR. For example, the lower region BR of the chamber 100 may be a region in which the substrate W is subjected to a vapor deposition process. For example, the upper region UR of the chamber 100 may be a region in which plasma including ions and radicals is generated, e.g., the lower region BR may be between a bottom of the chamber 100 and the upper region UR. The lower region BR of the chamber 100 and the upper region UR of the chamber 100 may be separated from each other by the shower head 140. A detailed description of the shower head 140 will be provided below.

The lower electrode 110 may be disposed inside the lower region BR of the chamber 100. The substrate W may be loaded onto the upper surface of the lower electrode 110. The lower electrode 110 may chuck the substrate W, using the voltage applied to the lower electrode 110.

Hereinafter, each of a first horizontal direction DR1 and a second horizontal direction DR2 may be defined as directions parallel to the upper surface of the lower electrode 110. The second horizontal direction DR2 may be defined as a direction perpendicular to the first horizontal direction DR1. A vertical direction DR3 may be defined as a direction perpendicular to each of the first horizontal direction DR1 and the second horizontal direction DR2. That is, the vertical direction DR3 may be defined as a direction perpendicular to the upper surface of the lower electrode 110.

The RF plate 111 may be disposed on the lower surface of the lower electrode 110. For example, a central portion of the RF plate 111 may protrude toward the bottom surface of the chamber 100. For example, as illustrated in FIG. 1, a width of the RF plate 111 in the first horizontal direction DR1 may be the same as a width of the lower electrode 110 in the first horizontal direction DR1. In another example, the width of the RF plate 111 in the first horizontal direction DR1 may differ from the width of the lower electrode 110 in the first horizontal direction DR1. The RF plate 111 may include a conductive material, e.g., aluminum (Al).

The RF rod 112 may be disposed below the RF plate 111. For example, the RF rod 112 may be connected to a protruding portion of the RF plate 111. The first power source P1 may supply RF (radio frequency) power to the RF rod 112. The RF power supplied to the first power source P1 may be supplied to the lower electrode 110 through the RF rod 112 and the RF plate 111.

The ground electrode 113 may surround the side walls of the RF rod 112. The ground electrode 113 may be spaced apart from the side walls of the RF rod 112. Also, the ground electrode 113 may be spaced apart from the RF plate 111.

The ground plate 114 may be disposed below the RF plate 111. The ground plate 114 may surround the side walls of the ground electrode 113. The ground plate 114 may abut, e.g., directly contact an edge of, the ground electrode 113. The ground plate 114 may abut the inner wall of the lower region BR of the chamber 100. The ground electrode 113 may be grounded with the inner wall of the lower region BR of the chamber 100 through the ground plate 114.

The insulating plate 121 may surround each of the side walls of the lower electrode 110 and the side walls of the RF plate 111. The insulating plate 121 may abut the ground plate 114. At least a part of the insulating plate 121 may abut the lower surface of the RF plate 111. The insulating plate 121 may include an insulating material, e.g., ceramic.

The focus ring 122 may be disposed on the edge of the upper surface of the lower electrode 110 and at least a part of the upper surface of the insulating plate 121. The focus ring 122 may surround a part of the upper side walls of the lower electrode 110. The focus ring 122 may have an annular shape. The focus ring 122 may include an insulating material.

The insulator ring 124 may surround the side walls of the insulating plate 121. The insulator ring 124 may abut the side walls of the insulating plate 121. The insulator ring 124 may be spaced apart from the focus ring 122. The insulator ring 124 may have an annular shape. The insulator ring 124 may include an insulating material.

The edge ring 123 may be disposed on a part of the upper surface of the insulating plate 121 and on the upper surface of the insulator ring 124. The edge ring 123 may surround the side walls of the focus ring 122. The edge ring 123 may abut each of the insulating plate 121, the insulator ring 124, and the focus ring 122. The edge ring 123 may have an annular shape. The edge ring 123 may include an insulating material.

The baffle unit 130 (e.g., a baffle) may be disposed between the insulator ring 124 and the side walls of the lower region BR of the chamber 100. For example, as illustrated in FIG. 1, the baffle unit 130 may abut each of the inner wall of the lower region BR of the chamber 100 and the side walls of the insulator ring 124. In another example, the baffle unit 130 may be spaced apart from either the inner wall of the lower region BR of the chamber 100 or the side wall of the insulating plate 121.

The baffle unit 130 may have an annular shape. The baffle unit 130 may include a plurality of baffle holes that penetrate the baffle unit 130 in the vertical direction DR3. Each of the plurality of baffle holes may be spaced apart from each other.

The gas outlet 135 may be formed in the lower region BR of the chamber 100. For example, the gas outlet 135 may be formed in the bottom surface of the chamber 100. Process gas existing inside the lower region BR of the chamber 100 may pass through the baffle unit 130, and may be discharged to the outside of the chamber 100 through the gas outlet 135.

The shower head 140 may be disposed inside the chamber 100. For example, the shower head 140 may abut, e.g., directly contact, the inner walls of the chamber 100. The chamber 100 may be separated into the lower region BR and the upper region UR by the shower head 140. For example, the lower region BR of the chamber 100 and the upper region UR of the chamber 100 may be completely separated by the shower head 140. For example, as illustrated in FIG. 1, the shower head 140 may have a flat plate shape. In another example, the shower head 140 may have any suitable shape that separate the lower region BR of the chamber 100 and the upper region UR of the chamber 100.

A plurality of source gas supply lines 165 may penetrate the side walls of the upper region UR of the chamber 100. The source gas supply unit 160 (e.g., a source gas supply) may surround the outer wall of the upper region UR of the chamber 100. For example, as shown in FIG. 3, the source gas supply unit 160 may have an annular shape. The source gas supply unit 160 may be connected to the plurality of source gas supply lines 165. The source gas supply unit 160 may supply the source gas into the upper region UR of the chamber 100 through the plurality of source gas supply lines 165. For example, the source gas may include at least one inert gas, e.g., at least one of argon (Ar), helium (He), oxygen (O₂), nitrogen (N₂), and fluorinated nitrogen (NF₃).

The window 170 may be disposed above the upper region UR of the chamber 100. For example, the window 170 may enclose the upper region UR of the chamber 100. The window 170 may include an insulating material, e.g., aluminum oxide (Al₂O₃).

The antenna 180 may be disposed above the window 170. A second power source P2 may supply RF power to the antenna 180. The antenna 180 may generate a magnetic field and an electric field inside the upper region UR of the chamber 100, using RF power supplied from the second power source P2. Plasma may be generated inside the upper region UR of the chamber 100 (e.g., inductively coupled plasma (ICP)), using the magnetic field and electric field generated by the antenna 180 and the source gas. The plasma may include ions and radicals.

A plurality of plasma inlet holes 141 may be disposed in the shower head 140. Each of the plurality of plasma inlet holes 141 may penetrate the shower head 140 in the vertical direction DR3, e.g., each of the plurality of plasma inlet holes 141 may penetrate an entire thickness of the shower head 140 in the vertical direction DR3. The plurality of plasma inlet holes 141 may be spaced apart from each other, e.g., the plurality of plasma inlet holes 141 may be spaced apart from each other along a radial direction and a circumferential direction of the shower head 140 (FIG. 2). For example, each of the plurality of plasma inlet holes 141 may be formed entirely in the shower head 140. For example, the diameter of one plasma inlet hole 141 may have a range from 15 mm to 50 mm.

The plasma generated inside the upper region UR of the chamber 100 may flow into the lower region BR of the chamber 100 through the plurality of plasma inlet holes 141. In this case, both ions and radicals generated inside the upper region UR of the chamber 100 may flow into the lower region BR of the chamber 100 through the plurality of plasma inlet holes 141.

Accordingly, ions and radicals may also exist inside the lower region BR of the chamber 100. However, plasma including ions and radicals is not generated inside the lower region BR of the chamber 100. That is, the ions and radicals existing inside the lower region BR of the chamber 100 may only include the ions and radicals that have flowed into the lower region BR of the chamber 100 from the upper region UR of the chamber 100. For example, there is no RF power supplied directly to the lower region BR of the chamber 100, except the RF power supplied to the lower electrode 110.

A plurality of process gas supply holes 142 may be disposed in the shower head 140. Each of the plurality of process gas supply holes 142 may open toward the lower surface of the shower head 140. Each of the plurality of process gas supply holes 142 does not open toward the upper surface of the shower head 140, e.g., so the plurality of process gas supply holes 142 may extend only partially into the shower head 140 (FIG. 1). Each of the plurality of process gas supply holes 142 may be spaced apart from each other, e.g., the plurality of process gas supply holes 142 may be spaced apart from each other along a radial direction and a circumferential direction of the shower head 140 (FIG. 2). Each of the plurality of process gas supply holes 142 may be disposed between adjacent ones of the plurality of plasma inlet holes 141.

For example, each of the plurality of process gas supply holes 142 may be connected to each other inside the shower head 140, e.g., the plurality of process gas supply holes 142 may be interconnected and in fluid communication with each other through a supply line. For example, the diameter of one plasma inlet hole 141 may be greater than the diameter of one process gas supply hole 142. The process gas may be supplied to the interior of the lower region BR of the chamber 100 through the plurality of process gas supply holes 142. The process gas may include materials for forming a deposition film on the substrate W. For example, if the deposition film formed on the substrate W includes carbon (C) atoms, the process gas may include at least one of CH₄, C₂H₂ and C₃H₆.

The process gas supply line 155 may penetrate the side walls of the chamber 100. The process gas supply line 155 may be connected to each of the plurality of process gas supply holes 142. The process gas supply unit 150 (e.g., a process gas supply) may be connected to the process gas supply line 155. The process gas supply unit 150 may supply the process gas to the lower region BR of the chamber 100 through the process gas supply line 155 and the plurality of process gas supply holes 142.

The plasma processing apparatus according to some embodiments of the present disclosure may easily control the process, by separating the upper region UR of the chamber 100 to which the source gas is supplied and the lower region BR of the chamber 100 to which the process gas is supplied, using the shower head 140. Also, by disposing the plasma inlet hole 141 having a relatively large diameter in the shower head 140, the ions generated in the upper region UR of the chamber 100 may flow into the lower region BR of the chamber 100 through the plasma inlet hole 141. Accordingly, the ion energy can be effectively adjusted inside the lower region BR of the chamber 100 in which the deposition process is performed.

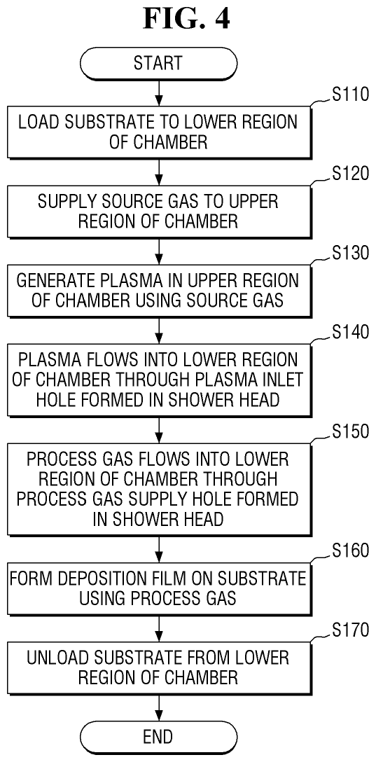

A method for fabricating a semiconductor device using a plasma processing apparatus according to some embodiments of the present disclosure will be described below with reference to FIGS. 4 to 8.

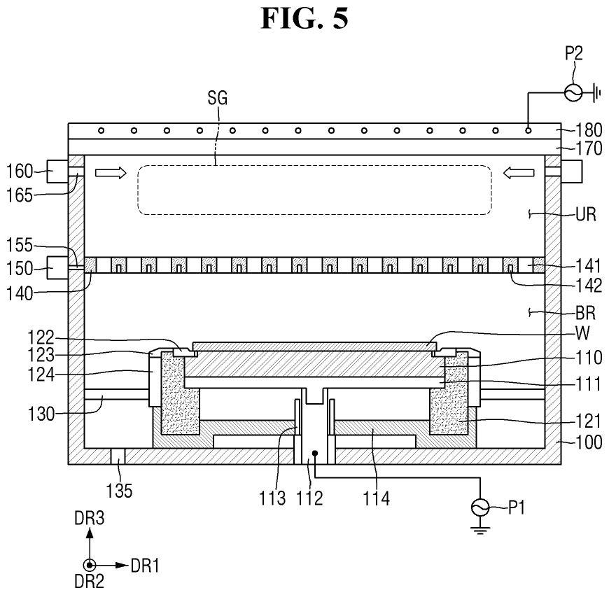

FIG. 4 is a flow chart for explaining a method for fabricating a semiconductor device using a plasma processing apparatus according to some embodiments of the present disclosure. FIGS. 5 to 8 are stages in a method for fabricating a semiconductor device using a plasma processing apparatus according to some embodiments of the present disclosure.

Referring to FIGS. 4 and 5, a substrate W may be loaded inside the lower region BR of the chamber 100 (S110). The substrate W may be loaded onto the upper surface of the lower electrode 110.

Subsequently, the source gas SG may be supplied into the upper region UR of the chamber 100 (S120). The source gas SG supplied from the source gas supply unit 160 may be supplied into the upper region UR of the chamber 100 through the source gas supply line 165. For example, the source gas SG supplied from the source gas supply unit 160 that surrounds the outer wall of the upper region UR of the chamber 100 may be supplied into the upper region UR of the chamber 100 through the source gas supply line 165 that penetrates the side walls of the upper region UR of the chamber 100. In another example, the source gas SG may be supplied from the upper part of the chamber 100.

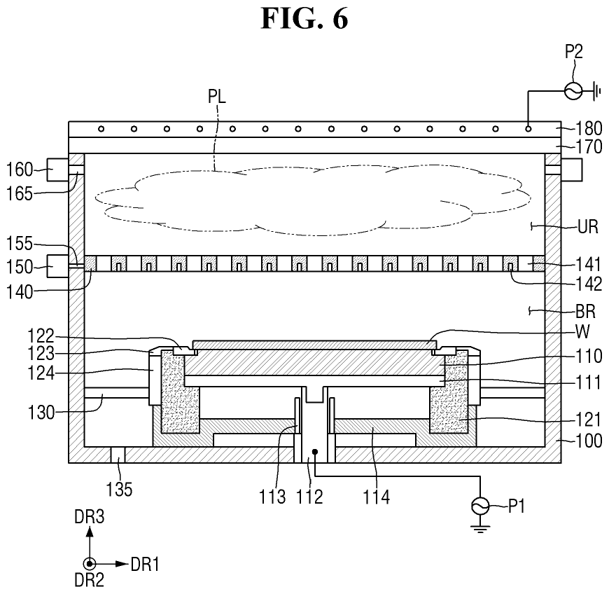

Referring to FIGS. 4 and 6, plasma PL including ions and radicals may be generated using the source gas (SG of FIG. 5) inside the upper region UR of the chamber 100 (S130).

For example, the antenna 180 may generate magnetic and electric fields inside the upper region UR of the chamber 100, using RF power supplied from the second power source P2. Next, the plasma PL including the ions and radicals may be generated inside the upper region UR of the chamber 100, using the magnetic field and electric field emitted from the antenna 180 and the source gas SG supplied from the source gas supply unit 160.

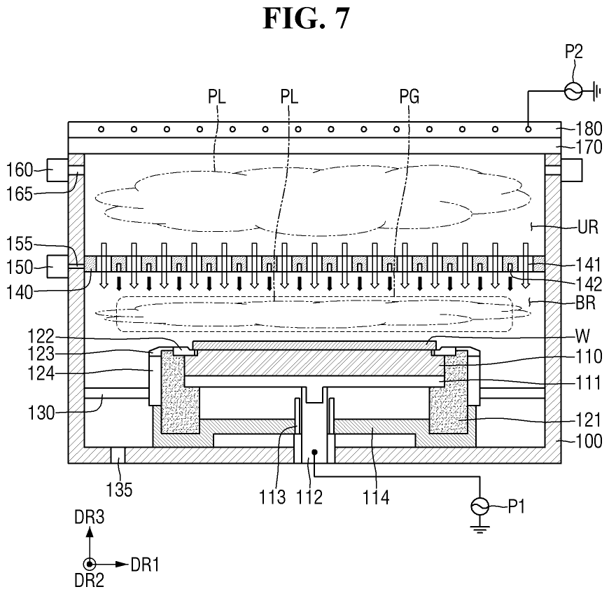

Referring to FIGS. 4 and 7, the plasma PL may flow into the lower region BR of the chamber 100 through the plurality of plasma inlet holes 141 formed in the shower head 140 (S140). In this case, the plasma PL (indicated by white arrows in FIG. 7) that has flowed into the lower region BR of the chamber 100 may include both ions and radicals. By forming the plurality of plasma inlet holes 141 relatively large in size, the ions existing inside the upper region UR of the chamber 100 may flow into the lower region BR of the chamber 100 through the plurality of plasma inlet holes 141.

Also, the process gas PG may be supplied into the lower region BR of the chamber 100 through the plurality of process gas supply holes 142 formed in the shower head 140 (S150). For example, the process gas PG (indicated by black arrows in FIG. 7) supplied from the process gas supply unit 150 may be supplied to the interior of the lower region BR of the chamber 100 through the process gas supply line 155 penetrating the side wall of the chamber 100 and the plurality of process gas supply holes 142.

In some embodiments, any one of the inflow of plasma PL into the lower region BR of the chamber 100 and the supply of the process gas PG into the lower region BR of the chamber 100 may be performed first. In some other embodiments, the inflow of the plasma PL into the lower region BR of the chamber 100 and the supply of the process gas PG into the lower region BR of the chamber 100 may be performed simultaneously.

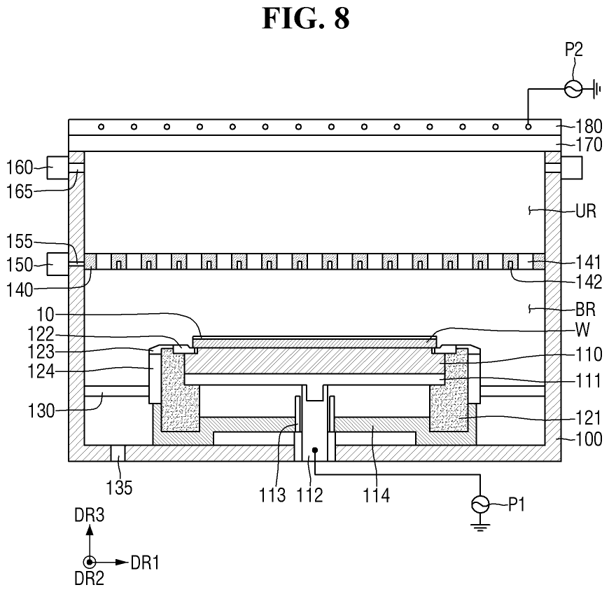

Referring to FIGS. 4 and 8, a deposition film 10 may be formed on the substrate W, using ions, radicals, and the process gas (PG of FIG. 7) inside the lower region BR of the chamber 100 (S160). For example, when the process gas (PG of FIG. 7) includes at least one of CH₄, C₂H₂, and C₃H₆, the deposition film 10 formed on the substrate W may include carbon (C) atoms.

Subsequently, after forming the deposition film 10 on the substrate W, the substrate W may be unloaded from the lower region BR of the chamber 100 (S170). The deposition film 10 may be formed on the substrate W through such a fabricating process.

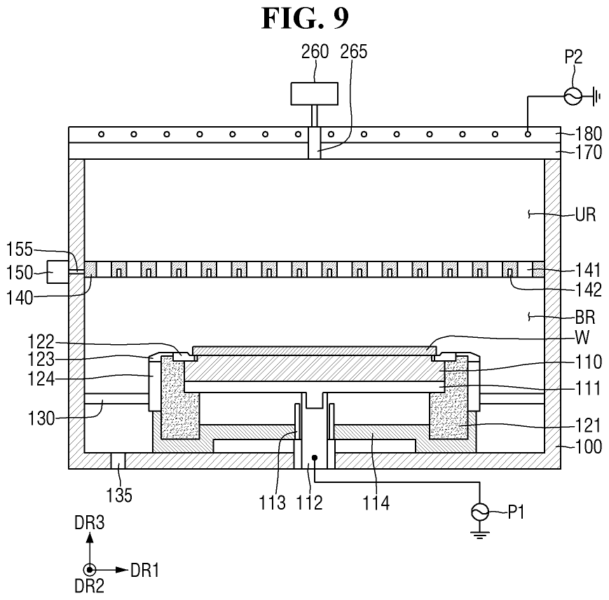

Hereinafter, a plasma processing apparatus according to some other embodiments of the present disclosure will be described with reference to FIG. 9. Differences from the plasma processing apparatus shown in FIGS. 1 to 3 will be mainly described.

FIG. 9 is a diagram for explaining a plasma processing apparatus according to some other embodiments of the present disclosure.

Referring to FIG. 9, the plasma processing apparatus according to some other embodiments of the present disclosure may supply the source gas from the upper part of the chamber 100 into the upper region UR of the chamber 100.

For example, a source gas supply line 265 may penetrate the window 170 and the antenna 180 in the vertical direction DR3. The source gas supply unit 260 may supply the source gas into the upper region UR of the chamber 100 through the source gas supply line 265.

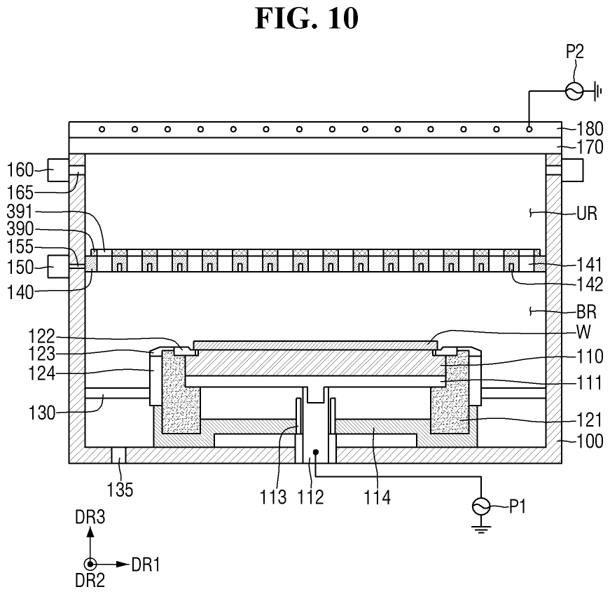

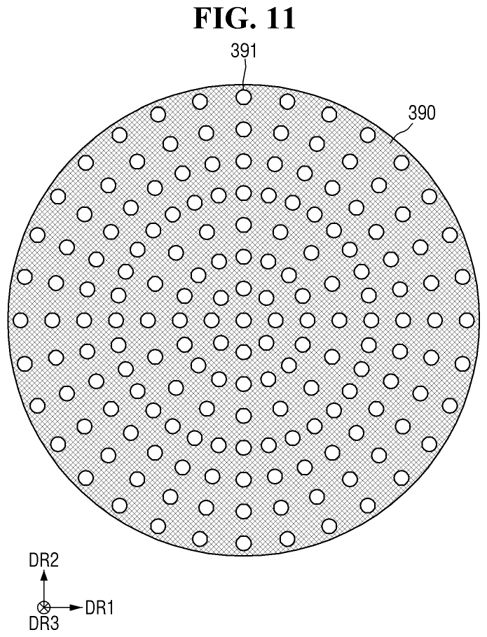

Hereinafter, a plasma processing apparatus according to still other embodiments of the present disclosure will be described with reference to FIGS. 10 and 11. Differences from the plasma processing apparatus shown in FIGS. 1 to 3 will be mainly described.

FIG. 10 is a diagram for explaining a plasma processing apparatus according to some other embodiments of the present disclosure. FIG. 11 is a plan view for explaining a plasma adjusting unit shown in FIG. 10.

Referring to FIGS. 10 and 11, a plasma processing apparatus according to some other embodiments of the present disclosure may adjust an amount of plasma flowing into the lower region BR of the chamber 100, using a plasma adjusting unit 390.

For example, the plasma adjusting unit 390 (e.g., a plasma adjuster) may be connected to the upper surface of the shower head 140. A plurality of plasma adjusting unit holes 391 may be disposed in the plasma adjusting unit 390. Each of the plurality of plasma adjusting unit holes 391 may penetrate the plasma adjusting unit 390 in the vertical direction DR3. Each of the plurality of plasma adjusting unit holes 391 may be spaced apart from each other. Each of the plurality of plasma adjusting unit holes 391 may completely overlap each of the plurality of plasma inlet holes 141 in the vertical direction DR3.

For example, the plasma adjusting unit 390 may move along the upper surface of the shower head 140 in the first horizontal direction DR1 or the second horizontal direction DR2. When the plasma adjusting unit 390 moves, each of the plurality of plasma adjusting unit holes 391 may be misaligned with each of the plurality of plasma inlet holes 141 in the vertical direction DR3. That is, when the plasma adjusting unit 390 moves, each of the plurality of plasma inlet holes 141 and at least a part of the plasma adjusting unit 390 may overlap in the vertical direction DR3. Accordingly, the sizes of each of the plurality of plasma inlet holes 141 exposed to the upper region UR of the chamber 100 may be adjusted, and the amount of plasma flowing into the lower region BR of the chamber 100 may be adjusted.

In some other embodiments, the plasma adjusting unit 390 and the plurality of plasma adjusting unit holes 391 may also be disposed in the plasma processing apparatus shown in FIG. 9.

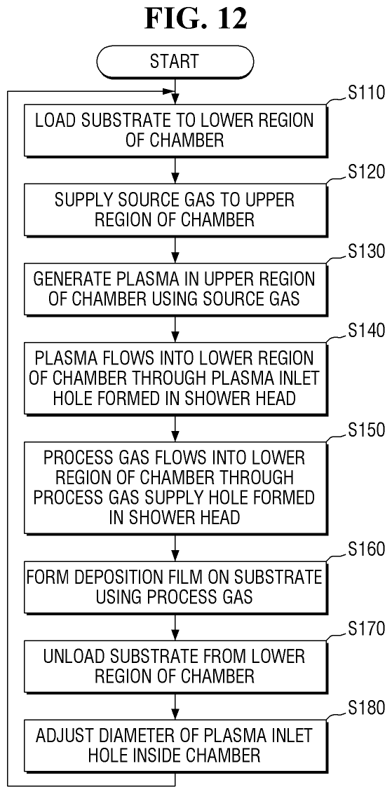

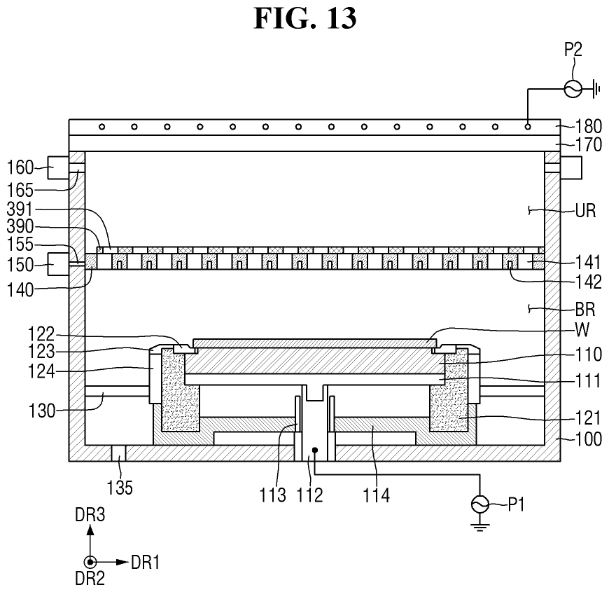

Hereinafter, a method for fabricating a semiconductor device using a plasma processing apparatus according to still other embodiments of the present disclosure will be described with reference to FIGS. 12 and 13. Differences from the method for fabricating the semiconductor device shown in FIGS. 4 to 8 will be mainly described.

Referring to FIGS. 12 and 13, after the fabricating processes shown in FIGS. 4 to 8 are performed, the diameters of each of the plurality of plasma inlet holes 141 may be adjusted inside the chamber 100 (S180).

For example, after performing the fabricating processes shown in FIGS. 4 to 8, the plasma adjusting unit 390 may move along the upper surface of the shower head 140 in the first horizontal direction DR1. As the plasma adjusting unit 390 moves, as shown in FIG. 13, each of the plurality of plasma adjusting unit holes 391 may be misaligned with each of the plurality of plasma inlet holes 141 in the vertical direction DR3.

Accordingly, the sizes of each of the plurality of plasma inlet holes 141 exposed to the upper region UR of the chamber 100 are adjusted, and the amount of plasma flowing (e.g., provided, supplied or delivered) into the lower region BR of the chamber 100 may be adjusted. Subsequently, another substrate W may be loaded into the lower region BR of the chamber 100 (S110). Subsequently, the fabricating processes shown in FIGS. 4 to 8 may be repeatedly performed.

Through such fabricating processes, a plasma processing efficiency can be improved, by adjusting the sizes of the plurality of plasma inlet holes 141 inside the chamber 100 without replacing the shower head 140.

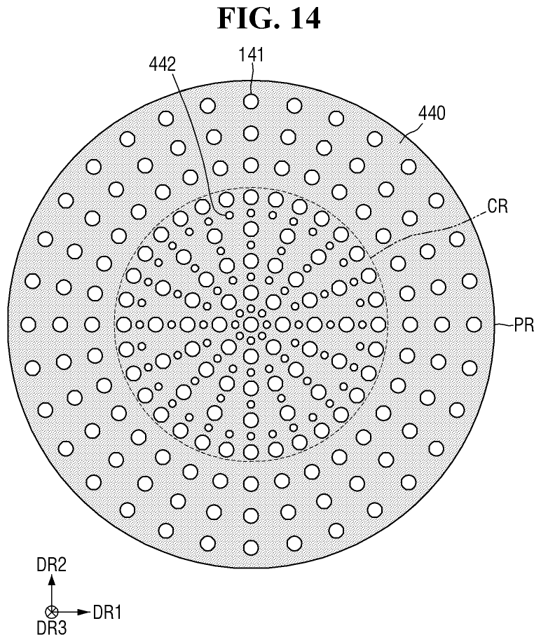

Hereinafter, a plasma processing apparatus according to still other embodiments of the present disclosure will be described with reference to FIG. 14. Differences from the plasma processing apparatus shown in FIGS. 1 to 3 will be mainly described.

FIG. 14 is a plan view for explaining a shower head of a plasma processing apparatus according to some other embodiments of the present disclosure.

Referring to FIG. 14, in a shower head 440 disposed in the plasma processing apparatus according to some other embodiments of the present disclosure, a plurality of process gas supply holes 442 may be disposed only in some regions.

For example, the shower head 440 may include a central region CR formed on the substrate W (e.g., the central region CR may vertically overlap a center of the lower electrode 110), and an edge region PR that surrounds the central region CR. A plurality of plasma inlet holes 141 may be disposed entirely in each of the central region CR of the shower head 440 and the edge region PR of the shower head 440. A plurality of process gas supply holes 442 may be disposed only in the central region CR of the shower head 440. That is, the plurality of process gas supply holes 442 are not disposed in the edge region PR of the shower head 440.

In some other embodiments, a plasma adjusting unit (390 of FIG. 10) and a plurality of plasma adjusting unit holes (391 of FIG. 10) may be disposed on the upper surface of the shower head 440.

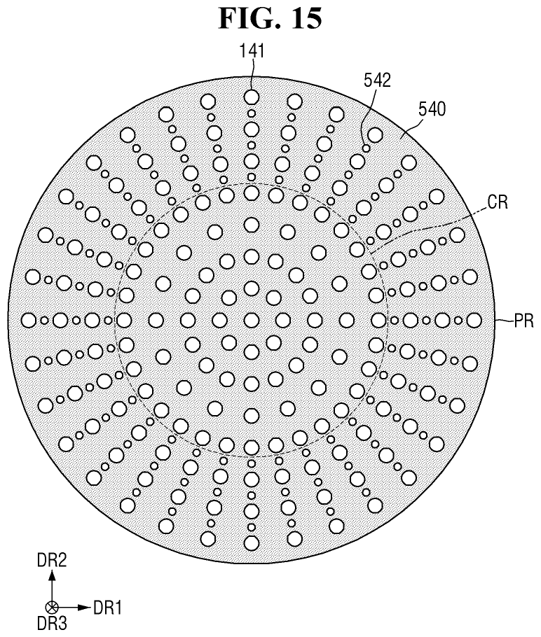

Hereinafter, a plasma processing apparatus according to some other embodiments of the present disclosure will be described with reference to FIG. 15. Differences from the plasma processing apparatus shown in FIGS. 1 to 3 will be mainly described.

FIG. 15 is a plan view for explaining a shower head of a plasma processing apparatus according to some other embodiments of the present disclosure.

Referring to FIG. 15, in a shower head 540 disposed in the plasma processing apparatus according to some other embodiments of the present disclosure, a plurality of process gas supply holes 542 may be disposed only in some regions.

For example, the shower head 540 may include a central region CR formed on the substrate (W of FIG. 1) and an edge region PR that surrounds the central region CR. A plurality of plasma inlet holes 141 may be disposed entirely in each of the central region CR of the shower head 540 and the edge region PR of the shower head 540. The plurality of process gas supply holes 542 may be disposed only in the edge region PR of the shower head 540. That is, the plurality of process gas supply holes 542 are not disposed in the central region CR of the shower head 540.

In some other embodiments, a plasma adjusting unit (390 of FIG. 10) and a plurality of plasma adjusting unit holes (391 of FIG. 10) may be disposed on the upper surface of the shower head 540.

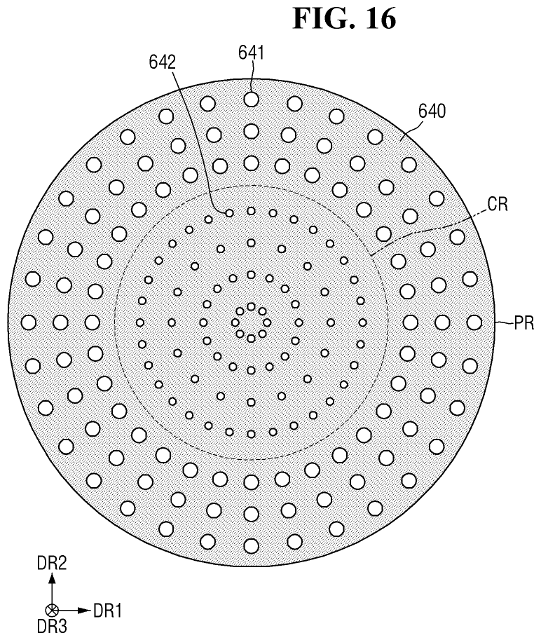

Hereinafter, a plasma processing apparatus according to still other embodiments of the present disclosure will be described with reference to FIG. 16. Differences from the plasma processing apparatus shown in FIGS. 1 to 3 will be mainly described.

FIG. 16 is a plan view for explaining a shower head of a plasma processing apparatus according to some other embodiments of the present disclosure.

Referring to FIG. 16, in a shower head 640 disposed in the plasma processing apparatus according to still some other embodiments of the present disclosure, a plurality of plasma inlet holes 641 and a plurality of process gas supply holes 642 may be disposed in different regions from each other.

For example, the shower head 640 may include a central region CR formed on the substrate (W of FIG. 1), and an edge region PR that surrounds the central region CR. The plurality of plasma inlet holes 641 may be disposed only in the edge region PR of the shower head 640. That is, the plurality of plasma inlet holes 641 are not disposed in the central region CR of the shower head 640. The plurality of process gas supply holes 642 may be disposed only in the central region CR of the shower head 540. That is, the plurality of process gas supply holes 642 are not disposed in the edge region PR of the shower head 640.

In some other embodiments, a plasma adjusting unit (390 of FIG. 10) and a plurality of plasma adjusting unit holes (391 of FIG. 10) may be disposed on the upper surface of the shower head 640.

By way of summation and review, the ACL process may be performed by a capacitively coupled plasma (CCP) equipment. However, a high ion energy and a low pressure are required to form a DLC film. While equipment that utilizes a magnetic field by adding a magnet to the existing CCP type equipment was developed to form the DLC film, such equipment has a very complicated structure and may cause a dispersion problem due to non-uniformity of the magnetic field.

In contrast, aspects of the present disclosure provide a plasma processing apparatus that easily controls the process by separating an upper region of a chamber, to which a source gas is supplied, and a lower region of the chamber, to which the process gas is supplied, using a shower head, and a method for fabricating a semiconductor device using the same. Aspects of the present disclosure also provide a plasma processing apparatus in which a plasma inlet hole having a relatively large diameter is disposed in a shower head, such that ions generated in the upper region of the chamber may flow into the lower region of the chamber pass through the plasma inlet hole, thereby effectively controlling the ion energy in the lower region of the chamber in which the deposition process is performed on the substrate, and a method for fabricating a semiconductor device using the same.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1.-7. (canceled)

8. A plasma processing apparatus, comprising:
a chamber including a lower region and an upper region above the lower region, the upper region being a region in which a plasma including ions and radicals is generated, and the lower region being a region in which a vapor deposition process is performed on a substrate;
a lower electrode inside the lower region of the chamber, the substrate being loaded onto the lower electrode;
a shower head inside the chamber, the shower head separating the lower region and the upper region;
plasma inlet holes penetrating the shower head in a vertical direction, the plasma inlet holes being configured to allow the ions and the radicals flow from the upper region to the lower region of the chamber;
process gas supply holes in the shower head, the process gas supply holes being configured to supply a process gas to the lower region of the chamber;
a process gas supply configured to supply the process gas to the process gas supply holes; and
an antenna on the upper region of the chamber, the antenna being configured to generate a magnetic field and an electric field inside the upper region of the chamber.

9. The plasma processing apparatus as claimed in claim 8, wherein a diameter of each of the plasma inlet holes is greater than a diameter of each of the process gas supply holes.

10. The plasma processing apparatus as claimed in claim 8, wherein a diameter of each of the plasma inlet holes is within a range of 15 mm to 50 mm.

11. The plasma processing apparatus as claimed in claim 8, wherein the chamber is configured to have the plasma generated only in the upper region among the lower region and the upper region, such that the ions and the radicals in the lower region are provided from the upper region through the plasma inlet holes.

12. The plasma processing apparatus as claimed in claim 8, wherein each of the process gas supply holes is between two of the plasma inlet holes.

13. The plasma processing apparatus as claimed in claim 8, further comprising:
source gas supply lines penetrating a side wall of the chamber; and
a source gas supply configured to supply a source gas to the upper region of the chamber through the source gas supply lines, the source gas supply having an annular shape that surrounds an outer wall of the chamber.

14. The plasma processing apparatus as claimed in claim 8, further comprising:
a source gas supply line penetrating the antenna; and
a source gas supply configured to supply a source gas to the upper region of the chamber through the source gas supply line.

15. The plasma processing apparatus as claimed in claim 8, further comprising:
a plasma adjuster connected to an upper surface of the shower head; and
plasma adjusting holes in the plasma adjuster, at least some of the plasma adjusting holes overlapping the plasma inlet holes in the vertical direction, respectively,
wherein the plasma adjuster is moveable to adjust an overlap between the plasma adjusting holes and the plasma inlet holes to adjust sizes of the plasma inlet holes exposed to the upper region.

16. The plasma processing apparatus as claimed in claim 8, wherein:
the shower head includes a central region vertically overlapping the lower electrode, and an edge region that surrounds the central region,
the plasma inlet holes are in each of the central region and the edge region, and
the process gas supply holes are only in the central region among the central region and the edge region.

17. The plasma processing apparatus as claimed in claim 8, wherein:
the shower head includes a central region vertically overlapping the lower electrode, and an edge region that surrounds the central region,
the plasma inlet holes are in each of the central region and the edge region, and
the process gas supply holes are only in the edge region among the central region and the edge region.

18. The plasma processing apparatus as claimed in claim 8, wherein:
the shower head includes a central region vertically overlapping the lower electrode, and an edge region that surrounds the central region,
the plasma inlet holes are only in the edge region among the central region and the edge region, and
the process gas supply holes are only in the central region among the central region and the edge region.

19. A plasma processing apparatus, comprising:
a chamber including a lower region and an upper region above the lower region, the upper region being a region in which a plasma including ions and radicals is generated, the lower region being a region in which a vapor deposition process is performed on a substrate, and the plasma being generated only in the upper region among the lower region and the upper region of the chamber;
a shower head inside the chamber, the shower head separating the lower region and the upper region;
plasma inlet holes penetrating the shower head in a vertical direction, the plasma inlet holes being configured to allow the ions and the radicals flow from the upper region to the lower region of the chamber;
process gas supply holes in the shower head, the process gas supply holes being configured to supply a process gas to the lower region of the chamber, and a diameter of each of the plasma inlet holes being greater than a diameter of each of the process gas supply holes;
a process gas supply configured to supply the process gas to the process gas supply holes; and
an antenna on the upper region of the chamber, the antenna being configured to generate a magnetic field and an electric field inside the upper region.

20. The plasma processing apparatus as claimed in claim 19, wherein each of the process gas supply holes is between two of the plasma inlet holes.

21. The plasma processing apparatus as claimed in claim 19, wherein a diameter of each of the plasma inlet holes is within a range of 15 mm to 50 mm.

22. The plasma processing apparatus as claimed in claim 19, further comprising:
a plasma adjuster connected to an upper surface of the shower head; and
plasma adjusting holes in the plasma adjuster, at least some of the plasma adjusting holes overlapping the plasma inlet holes in the vertical direction, respectively,
wherein the plasma adjuster is moveable to adjust an overlap between the plasma adjusting holes and the plasma inlet holes to adjust sizes of the plasma inlet holes exposed to the upper region.

23. The plasma processing apparatus as claimed in claim 19, wherein:
the shower head includes a central region vertically overlapping the lower electrode, and an edge region that surrounds the central region,
the plasma inlet holes are in each of the central region and the edge region, and
the process gas supply holes are only in the central region among the central region and the edge region.

24. A plasma processing apparatus, comprising:
a chamber including a lower region and an upper region above the lower region, the upper region being a region in which a plasma including ions and radicals is generated, and the lower region being a region in which a vapor deposition process is performed on a substrate;
a lower electrode inside the lower region of the chamber, the substrate being loaded onto the lower electrode;
a shower head inside the chamber, the shower head separating the lower region and the upper region;
plasma inlet holes penetrating the shower head in a vertical direction, the plasma inlet holes being configured to allow the ions and the radicals flow from the upper region to the lower region of the chamber;
process gas supply holes in the shower head, the process gas supply holes being configured to supply a process gas to the lower region of the chamber; and
a process gas supply configured to supply the process gas to the process gas supply holes,
wherein each of the process gas supply holes is between two of the plasma inlet holes.

25. The plasma processing apparatus as claimed in claim 24, wherein a diameter of each of the plasma inlet holes is greater than a diameter of each of the process gas supply holes.

26. The plasma processing apparatus as claimed in claim 24, wherein the chamber is configured to have the plasma generated only in the upper region among the lower region and the upper region, such that the ions and the radicals in the lower region are provided from the upper region through the plasma inlet holes.

27. The plasma processing apparatus as claimed in claim 24, further comprising:
an antenna on the upper region of the chamber, the antenna being configured to generate a magnetic field and an electric field inside the upper region.
